(19) United States
(12) Patent Application Publication
(10) Pub. No.: US 2010/0262898 A1
(43) Pub. Date: Oct. 14, 2010

(54) INFORMATION PROCESSING DEVICE AND INFORMATION PROCESSING METHOD

(75) Inventors: Masaaki IKUTA, Akishima-shi (JP); Fumio YOSHIYA, Tachikawa-shi (JP); Kenji YOSHIDA, Akishima-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/823,971

(22) Filed: Jun. 25, 2010

Related U.S. Application Data
(63) Continuation of application No. 12/267,469, filed on Nov. 7, 2008.

(30) Foreign Application Priority Data
Apr. 28, 2008 (JP) 2008-117650

(51) Int. Cl. H03M 13/09; G06F 11/10

(52) U.S. Cl. 714/807; 714/E11.032

(57) ABSTRACT

An information processing device, comprising: a first encoder configured to encode data having an error detecting code in a first encoding format to generate first data; a second encoder configured to encode the first data in a second encoding format corresponding to decoding of the first encoding format to generate second data; and an error detector configured to perform error detection on the second data based on the error detecting code added to the data.

### CROSS-REFERENCE TO RELATED APPLICATIONS

This application is a continuation of U.S. patent application Ser. No. 12/267,469, filed Nov. 7, 2008, which is based upon and claims the benefit of priority from the prior Japanese Patent Application No. 2008-117650, filed on Apr. 28, 2008; the entire contents of which are incorporated herein by reference.

### BACKGROUND OF THE INVENTION

1. Field of the Invention

The present invention relates to an information processing device and an information processing method and, more specifically, to an information processing device and an information processing method to encode or decode data.

2. Description of the Related Art

Conventional information processing devices include one which encrypts data and records it on a magnetic recording disk when recording the data, and decrypts (decodes) the encrypted data and outputs it when reading the data from the magnetic recording disk (see, for example, JP-A 2001-236718 (KOKAI)).

### BRIEF SUMMARY OF THE INVENTION

The conventional information processing device has not verifies whether or not the encryption has succeeded when writing the data into a magnetic disk. Further, the device has not verified whether or not the decryption has succeeded when reading the data from the magnetic disk. Therefore, it could not prevent to record or output error data due to a malfunction caused by failure of an encryption circuit or cosmic radiation. In consideration of the above problems, an object of the present invention is to attain an information processing device and an information processing method in which output of error data is prevented.

An information processing device according to an aspect of the present invention includes: a first encoder configured to encode data having an error detecting code in a first encoding format to generate first data; a second encoder configured to encode the first data in a second encoding format corresponding to decoding of the first encoding format to generate second data; and an error detector configured to perform error detection on the second data based on the error detecting code added to the data.

An information processing method according to an aspect of the present implementation includes: encoding data having an error detecting code in a first encoding format to generate first data; encoding the first data in a second encoding format corresponding to decoding of the first encoding format to generate second data; and performing error detection on the second data based on the error detecting code added to the data.

### BRIEF DESCRIPTION OF THE DRAWINGS

FIG. 1 is a diagram showing a configuration of a magnetic disk device according to a first embodiment.

FIG. 2 is a diagram showing a configuration of a hard disk controller according to the first embodiment.

FIG. 3 is a flowchart showing a write operation of the magnetic disk device according to the first embodiment.

FIG. 4 is a flowchart showing a read operation of the magnetic disk device according to the first embodiment.

FIG. 5 is an illustration showing a configuration of an encoding section according to the first embodiment and flows of data.

FIG. 6 is a flowchart showing the operation at writing by the encoding section according to the first embodiment.

FIG. 7 is a flowchart showing the operation at reading by the encoding section according to the first embodiment.

FIG. 8 is a process chart showing the operation of the encoding section according to the first embodiment for each process.

FIG. 9 is an illustration showing a configuration of an encoding section according to a second embodiment.

FIG. 10 is a flowchart showing the operation at writing by the encoding section according to the second embodiment.

FIG. 11 is a flowchart showing the operation at reading by the encoding section according to the second embodiment.

FIG. 12 is an illustration showing a configuration of an encoding section according to a third embodiment and flows of data.

FIG. 13 is a flowchart showing the operation at writing by the encoding section according to the third embodiment.

FIG. 14 is a flowchart showing the operation at reading by the encoding section according to the third embodiment.

FIG. 15 is an illustration showing a configuration of an encoding section according to a fourth embodiment and flows of data.

FIG. 16 is a flowchart showing the operation at writing by the encoding section according to the fourth embodiment.

FIG. 17 is a flowchart showing the operation at reading by the encoding section according to the fourth embodiment.

FIG. 18 is an illustration showing a configuration of an encoding section according to a fifth embodiment and flows of data.

FIG. 19 is a flowchart showing the operation at writing by the encoding section according to the fifth embodiment.

FIG. 20 is a flowchart showing the operation at reading by the encoding section according to the fifth embodiment.

FIG. 21 is an illustration showing a configuration of an encoding section according to a sixth embodiment and flows of data.

FIG. 22 is a flowchart showing the operation at writing by the encoding section according to the sixth embodiment.

FIG. 23 is a flowchart showing the operation at reading by the encoding section according to the sixth embodiment.

FIG. 24 is diagram showing a configuration of a memory device according to a seventh embodiment.

FIG. 25 is a diagram showing a configuration of a NAND flash memory access controller according to the seventh embodiment.

FIG. 26 is a diagram showing a configuration of an Ethernet controller according to an eighth embodiment.

### DETAILED DESCRIPTION OF THE INVENTION

Hereinafter, embodiments of the present invention will be described in detail with reference to the drawings.

### First Embodiment

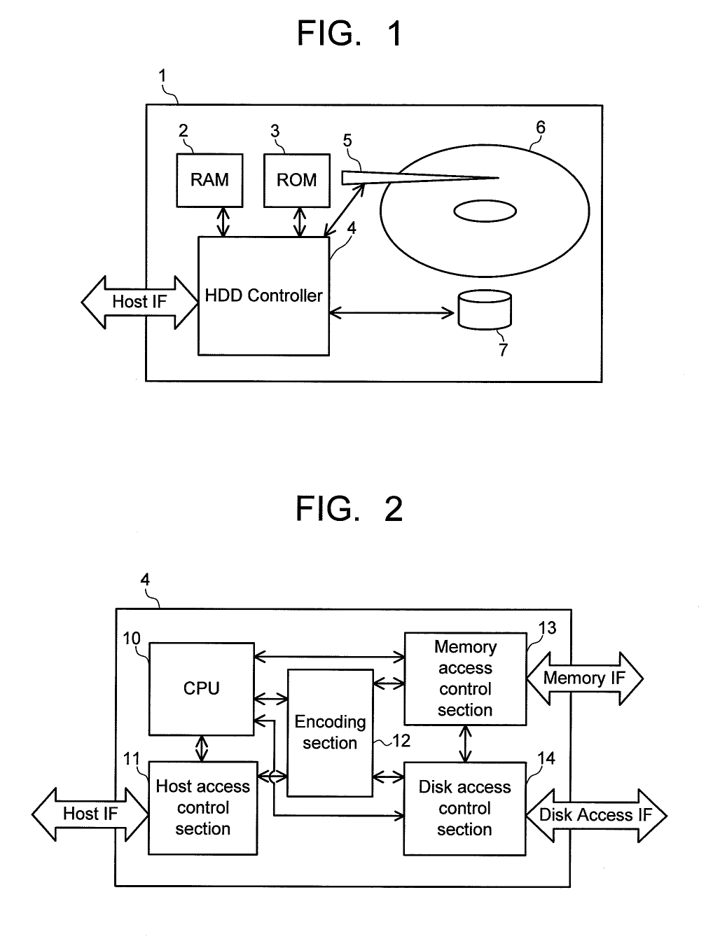

FIG. 1 is a diagram showing a configuration of a magnetic disk device 1 according to this embodiment. FIG. 2 is a diagram showing a configuration of a hard disk controller 4 according to this embodiment. The magnetic disk device 1 and the hard disk controller 4 constitute information processing devices, respectively. A RAM (random Access Memory) 2 is a used as a work area of a CPU (Central Processing Unit) 10. A ROM (Read Only Memory) 3 stores operation codes of the CPU 10. A header section 5 comprises a magnetic head and writes/reads data to/from a magnetic disk recording disk (recording medium) 6.

The magnetic recording disk 6 records data. The data recorded on the magnetic recording disk 6 has been encoded by an encoding section 12. A disk rotating motor 7 rotates the magnetic recording disk 6. The hard disk controller 4 controls the operation of the whole magnetic disk device 1. A host access control section 11 comprises a host interface and transmits/receives data according to a protocol such as PATA (Parallel Advanced Technology Attachment)/SATA (Serial Advanced Technology Attachment) or the like to/from a not-shown host.

The encoding section 12 encodes data received from the host by the host access control section 11 and decrypts (decodes) the data to be transmitted to the host. The encoding section 12 performs encryption, or encoding for purpose of compression of data. For the encryption of data, formats such as AES (Advanced Encryption Standard), DES (Data Encryption Standard), triple DES, C2, RSA can be used. Further, for encoding to compress data, reversible compression formats such as Huffman, LZ77, run-length can be used. Further, block sort to be used for pre-processing of compression or the like is also an object to be encoded by the encoding section 12 according to this embodiment.

An external memory access control section 13 comprises an external memory interface and transmits/receives data to/from the RAM 2 and the ROM 3. A disk access control section 14 comprises a disk access interface, and controls the header section 5 and the disk rotating motor 7 to write/read data to/from the magnetic recording disk 6. The disk access control section 14 constitutes a recording section.

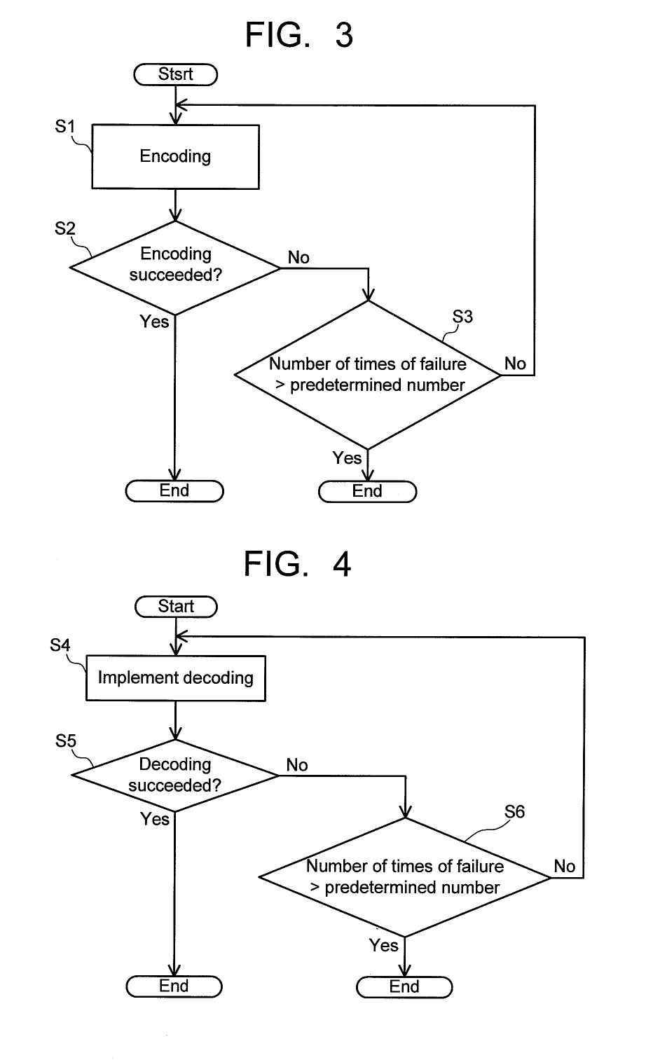

Next, the operations of the magnetic disk device 1 and the hard disk controller 4 of this embodiment will be described. FIG. 3 is a flowchart showing the write operation of the magnetic disk device 1 according to this embodiment. FIG. 4 is a flowchart showing the read operation of the magnetic disk device 1 according to this embodiment.

### (Operation at Writing of Data)

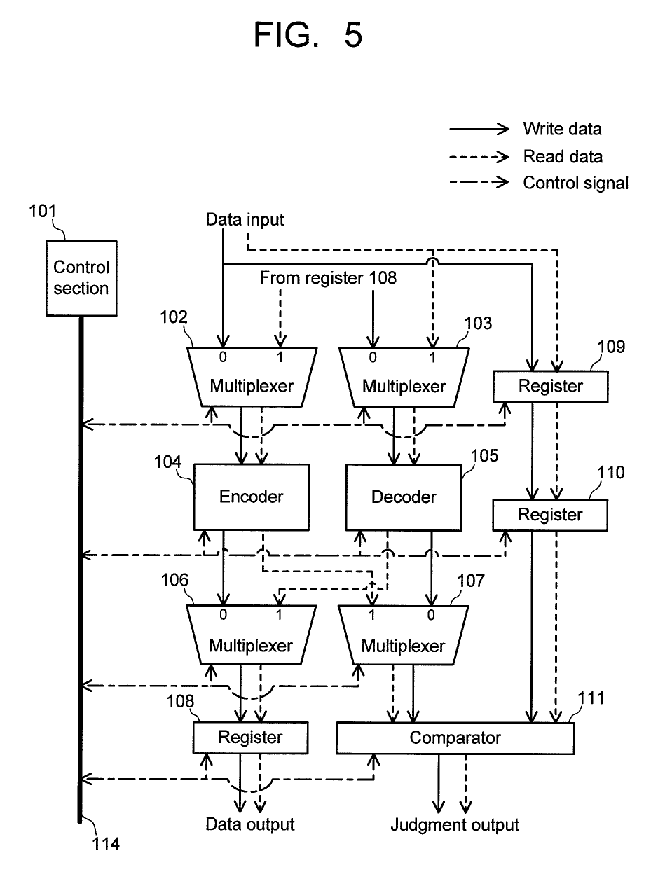

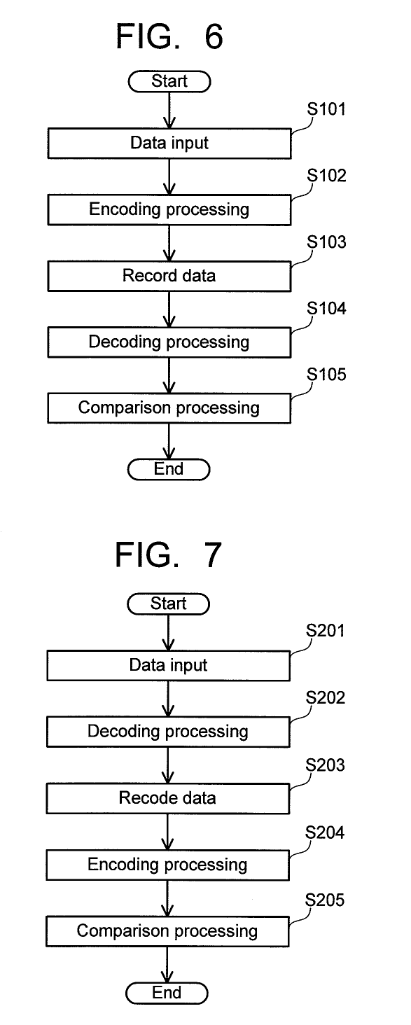

The host access control section 11 of the hard disk controller 4 receives a data write request signal from the host through the host interface. Then, the host access control section 11 receives data to be written into the magnetic recording disk 6 (hereinafter, referred to as write data) from the host and input it into the encoding section 12. The encoding section 12 encodes the inputted write data (Step S1) and verifies that encoding has succeeded (Step S2). Note that the verification method will be described in detail in the later description for FIGS. 5 and 6.

When the encoding of the write data has failed, the encoding section 12 discards the write data which has failed in encoding. Besides, when encoding of next write data has been started, the encoding section 12 also discards that write data. The CPU 10 counts the number of times of the encoding section 12 failed to encode write data, and verifies whether or not the number of times of failure to encode write data exceeds a previously set predetermined number (Step S3). When the number of times of failure to encode write data does not exceed the previously set predetermined number, the encoding section 12 returns to the processing in Step S1, and implements encoding again from the write data for which the encoding has failed.

When the number of times of failure to encode write data exceeds the previously set predetermined number, the host access control section 11 transmits an abort signal in response to the write request from the host. Besides, when the write data was able to be encoded in the processing in Step S2, the external memory access control section 13 writes the write data encoded in the encoding section 12 into the RAM 2. The external memory access control section 13 reads the encoded write data from the RAM 2 at a timing when it can access to the magnetic recording disk 6. The disk access control section 14 writes the write data read out from the RAM 2 into an address in the magnetic recording disk 6 which has been designated by the host.

### (Operation at Reading of Data)

The host access control section 11 of the hard disk controller 4 receives a data read request signal from the host through the host interface. The disk access control section 14 reads, from the magnetic recording disk 6, the data at the address designated by the read request signal (hereinafter, referred to as read data) from the host. The external memory access control section 13 writes, into the RAM 2, the data read out by the disk access control section 14.

The external memory access control section 13 inputs, into the encoding section 12, the read data written into the RAM 2. The encoding section 12 decodes the received read data (Step S4) and verifies whether or not the decoding has succeeded (Step S5). Note that the verification method will be described in detail in the later description for FIGS. 5 and 7. When the decoding of the read data has failed, the encoding section 12 discards the read data. Besides, when decoding of next read data has already been started, the encoding section 12 also discards that read data.

The encoding section 12 verifies whether or not the number of times of failure to decode exceeds a previously set predetermined number (Step S6). When the number of times of failure to decode does not exceed the previously set predetermined number, the encoding section 12 returns to the processing in Step S4, and implements decoding again from the read data for which the decoding has failed. When the number of times of failure to decode exceeds the previously set predetermined prescribed number, the encoding section 12 transmits an abort signal in response to the read request signal from the host. Besides, when the read data was able to be correctly decoded in the processing in Step S5, the host access control section 11 transmits the read data to the host through the host interface.

Note that as for the read data which is read from the magnetic recording disk 6 and written into the RAM 2 when the data read request from the host is received, the read data which has been written into the RAM 2 before reception of the data read request from the host may be used, if their addresses on the magnetic recording disk 6 are coincident with each other. For example, when the rear data is read from the address for which the data read request has been made by the host, data at a subsequent address which has not been requested from the host may be read and written into the RAM 2. The read data may be the write data for which a write request has been made from the host and thus written into the RAM 2.

FIG. 5 is an illustration showing a configuration of the encoding section 12 according to this embodiment and flows of data. Solid lines show the flow of write data. Dotted lines show the flow of read data. One-dotted chain lines show the flow of control signals.

An encoder 104 encodes data and outputs encoded data. A decoder 105 decodes data and outputs decoded data. Each of multiplexers 102, 103, 106, and 107 includes two input ports 0 and 1 and one output port. When write data is inputted, the port 0 is selected. When read data is inputted, the port 1 is selected.

Registers 108, 109 and 110 record data. A comparator 111 compares two pieces of data inputted from the multiplexer 107 and the register 110 and judges whether or not the inputted two pieces of data are coincident. A control section 101 is connected to the encoder 104, the decoder 105, the multiplexers 102, 103, 106 and 107, the registers 108, 109 and 110, and the comparator 111 via a bus 114.

The control section 101 transmits/receives control signals via the bus 114 to/from the encoder 104, the decoder 105, the multiplexers 102, 103, 106 and 107, the registers 108, 109 and 110, and the comparator 111. The control section 101 conducts control of the whole encoding section 12, such as switching between the input ports of the multiplexers 102, 103, 106 and 107, output of the judgment result in the comparator 111, input/output of the write data and read data, fetch of data into the registers 108, 109 and 110, and start and end of encoding of data in the encoder 10 and decoding of data in the decoder 105. Accordingly, the encoder 104, the decoder 105, the multiplexers 102, 103, 106 and 107, the registers 108, 109 and 110, and the comparator 111 operate according to the instruction from the control section 101. The control section 101 also acquires information necessary for encoding and decoding of data, from the host access control section 11.

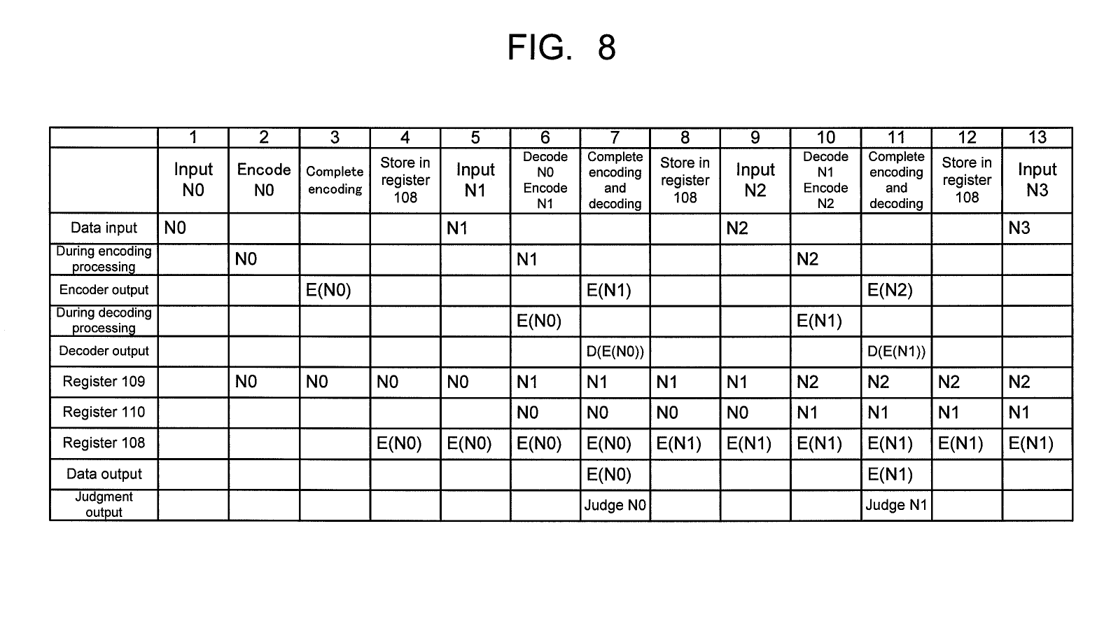

FIG. 6 is a flowchart showing the operation at writing by the encoding section 12 according to this embodiment. FIG. 7 is a flowchart showing the operation at reading by the encoding section 12 according to this embodiment. FIG. 8 is a process chart showing the operation of the encoding section according to this embodiment for each process. Note that in the following description, the write data or read data to be inputted shall be write data Nx or read data Nx (x=0, 1, 2, 3, . . . n:n is a positive integer). Further, it is assumed that data obtained by encoding the data Nx is data E(Nx), and data obtained by further decoding the encoded data E(Nx) is data D(E(Nx)). Further, it is assumed that data obtained by decoding the data Nx is D(Nx), and data obtained by further encoding the decoded data D(Nx) is data E(D(Nx)).

### (Operation at Writing of Data)

From the host access control section 11 into the encoding section 12, write data N0 is inputted (Step S101). The register 109 records the inputted write data N0 thereon. The multiplexer 102 inputs the write data N0 inputted into the port 0, into the encoder 104. The encoder 104 encodes the inputted write data N0 (Step S102).

The encoder 104 inputs the encoded write data E(N0) into the port 0 of the multiplexer 106. The multiplexer 106 inputs the inputted write data E(N0) into the register 108. The register 108 records the inputted write data E(N0) thereon (Step 5103). If next write data N1 can be inputted at this moment, the write data N1 is inputted from the host access control section 11 into the encoding section 12.

The register 108 inputs the recorded write data E(N0) into the port 0 of the multiplexer 103. The multiplexer 103 inputs the inputted write data E(N0) into the decoder 105. The decoder 105 decodes the inputted write data E(N0) (Step S104). The register 109 inputs the recorded write data N0 into the register 110. If next write data N1 has been inputted at this moment, the register 109 records the write data N1 thereon.

Further, the multiplexer 102 inputs the write data inputted to the port 0, into the encoder 104. The encoder 104 encodes the inputted write data N1. After completion of the decoding of the write data E(N0), the decoder 105 inputs the decoded write data D(E(N0)) into the port 0 of the multiplexer 107. The multiplexer 107 inputs the inputted write data D(E(N0)) into the comparator 111. The register 110 inputs the recorded write data N0 into the comparator 111.

The comparator 111 compares the inputted two pieces of write data D(E(N0)) and N0 (Step S105). If the write data before encoding has no error and encoding and decoding of all of the write data have succeeded, the same write data as that before encoding has been obtained, so that the two pieces of data D(E(N0)) and N0 are coincident, and therefore the comparator 111 outputs the judgment result of successful encoding. On the other hand, when there is an error in the write data before encoding, or if encoding and decoding of all of the write data have failed even one bit, the two pieces of write data D(E(N0)) and N0 are not coincident, and therefore the comparator 111 outputs the judgment result of encoding failure. Further, the register 108 outputs the recorded write data E(N0), but when the judgment result of encoding failure is outputted from the comparator 111, the write data E(N0) is discarded.

Further, if the encoding of the write data N1 has been completed, the encoder 104 inputs the encoded write data E(N1) into the port 0 of the multiplexer 106. The multiplexer 106 inputs the inputted write data E(N1) into the register 108. The register 108 records the inputted write data E(N1). Hereinafter, data processing of write data N2 and thereafter is performed in the same manner.

### (Operation at Reading of Data)

The read data N0 read from the magnetic recording disk 6 is inputted from the disk access control section 14 into the encoding section 12 (Step S201). The register 109 records the inputted read data N0 thereon. The multiplexer 103 inputs the read data N0 inputted to the port 1, into the decoder 105. The decoder 105 decodes the inputted read data N0 (Step S202).

The decoder 105 inputs the decoded read data D(N0) into the port 1 of the multiplexer 106. The multiplexer 106 inputs the inputted read data D(N0) into the register 108. The register 108 records the inputted read data D(N0) thereon (Step S203). If next read data N1 can be inputted at this moment, the read data N1 is inputted from the host access control section 11 into the encoding section 12.

The register 108 inputs the recorded read data D(N0) into the port 1 of the multiplexer 102. The multiplexer 102 inputs the inputted read data into the encoder 104. The encoder 104 encodes the inputted read data D(N0) (Step 5204). The register 109 inputs the recorded read data N0 into the register 110. If the next read data has been inputted at this moment, the register 109 records the read data N1 thereon.

The multiplexer 103 also inputs the read data N1 inputted to the port 1, into the decoder 105. The decoder 105 decodes the inputted read data N1. After completion of encoding of the read data D(N0), the encoder 104 inputs the encoded read data E(D(N0)) into the port 1 of the multiplexer 107. The multiplexer 107 inputs the inputted read data E(D(N0)) into the comparator 111. The register 110 inputs the recorded read data N0 into the comparator 111.

The comparator 111 compares the inputted two pieces of read data E(D(N0)) and N0 (Step S205). If the read data before decoding has no error and decoding and encoding of all of the read data have succeeded, the same read data as that before decoding has been obtained, so that the two pieces of data E(D(N0)) and N0 are coincident, and therefore the comparator 111 outputs the judgment result of successful decoding. On the other hand, when there is an error in the read data before decoding, or if decoding and encoding of all of the read data have failed even one bit, the two pieces of read data E(D(N0)) and N0 are not coincident, and therefore the comparator 111 outputs the judgment result of decoding failure. Further, the register 108 outputs the recorded read data D(N0), but when the judgment result of decoding failure is outputted from the comparator 111, the read data D(N0) is discarded.

Further, if the decoding of the read data N1 has been completed, the decoder 105 inputs the decoded read data D(N1) into the port 1 of the multiplexer 106. The multiplexer 106 inputs the inputted read data D(N1) into the register 108. The register 108 records the inputted read data D(N1) thereon. Hereinafter, data processing of read data N2 and thereafter is performed in the same manner.

Next, the operation of the encoding section 12 according to this embodiment will be described in detail for each process using FIG. 8.

### (Process 1)

The host access control section 11 inputs the write data N0 into the encoding section 12.

### (Process 2)

The register 109 records the inputted write data N0 thereon. Further, the encoder 104 starts the encoding processing of the write data N0 inputted via the multiplexer 102.

### (Process 3)

The encoder 104 completes the encoding processing of the write data N0 and inputs the encoded write data E(N0) into the multiplexer 106.

### (Process 4)

The register 108 records the write data E(N0) inputted via the multiplexer 106.

### (Process 5)

The host access control section 11 inputs the write data N1 into the encoding section 12.

### (Process 6)

The register 110 records the write data N0 recorded on the register 109. The decoder 105 starts the decoding processing of the write data E(N0) inputted from the register 108 via the multiplexer 103. The register 109 records the inputted write data N1. The encoder 104 starts the encoding processing of the write data N1 inputted via the multiplexer 102.

### (Process 7)

The decoder 105 completes the decoding processing of the write data E(N0) and inputs the decoded write data D(E(N0)) into the comparator 111 via the multiplexer 107. The encoder 104 completes the encoding processing of the write data N1 and inputs the encoded write data E(N1) into the multiplexer 106. The register 110 inputs the recorded write data N0 into the comparator 111. The comparator 111 judges whether or not the write data N0 inputted from the register 110 and the write data D(E(N0)) inputted from the decoder 105 are coincident. When the write data N0 inputted from the register 110 and the write data D(E(N0)) inputted from the decoder 105 are coincident, the comparator 111 outputs the judgment result of encoding success. The register 108 outputs the recorded write data E(N0).

### (Process 8)

The register 108 records the write data E(N1) inputted from the encoder 104 via the multiplexer 106.

### (Process 9)

The host access control section 11 inputs the write data N2 into the encoding section 12.

### (Process 10)

The register 110 records the write data N1 recorded on the register 109. The encoder 105 starts the decoding processing of the write data E(N1) inputted from the register 108 via the multiplexer 103. The register 109 records the inputted write data N2 thereon. The encoder 104 starts the encoding processing of the write data N2 inputted via the multiplexer 102.

### (Process 11)

The decoder 105 completes the decoding processing of the write data E(N1) and inputs the decoded write data D(E(N1)) into the comparator 111 via the multiplexer 107. The encoder 104 completes the encoding processing of the write data N2 and inputs the encoded write data E(N2) into the multiplexer 106. The register 110 inputs the recorded write data N1 into the comparator 111. The comparator 111 judges whether or not the write data N1 inputted from the register 110 and the write data D(E(N1)) inputted from the decoder 105 are coincident. When the write data N1 inputted from the register 110 and the write data D(E(N1)) inputted from the decoder 105 are coincident, the comparator 111 outputs the judgment result of encoding success. The register 108 outputs the recorded write data E(N1).

### (Process 12)

The register 108 records the write data E(N2) inputted from the encoder 104 via the multiplexer 106.

### (Process 13)

The host access control section 11 inputs write data N3 into the encoding section 12. Hereinafter, data processing of the write data N3 and thereafter is performed in the same manner. Note that this also applies to the processing of the rear operation of the read data.

It can be prevented to output error data and record it onto the magnetic recording disk 6 because whether or not the encoding of data has succeeded is verified when data is written into the magnetic recording disk 6 as described above. It can also be prevented to output and transmit error data because whether or not the decoding of data has succeeded is verified when data is read from the magnetic recording disk 6.

### Second Embodiment

When an error detecting code is added to data outside the encoding section 12 (in the hard disk controller or on the host side at writing of data), this added error detecting code can be used to judge whether or not encoding or the decoding has succeeded. In this embodiment, whether or not encoding or the decoding has succeeded is judged using the error detecting code.

For the error detection, parity, checksum, and CRC (Cyclic Redundancy Check) systems which can be used as the error detecting code. Further, the error can be detected even by an error correcting code. The error correcting codes include Read-Solomon code, Hamming code and so on which can used to realize the error correction. However, there is a limit in the number of bits which can be detected by each of the systems, and they can detect circuit failure and software error when the number of error bits does not exceed their detection abilities.

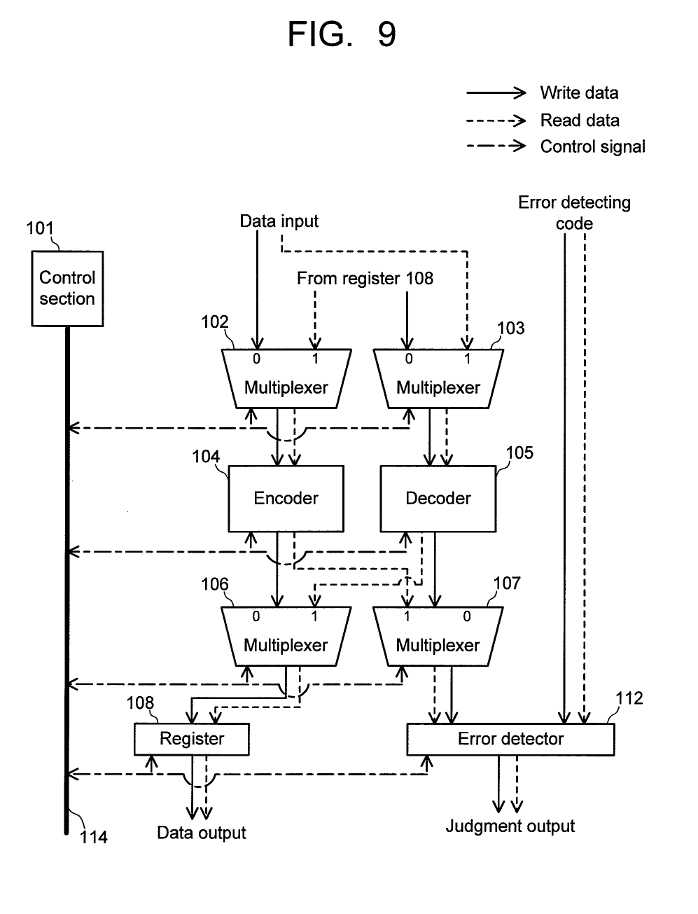

FIG. 9 is an illustration showing a configuration of a magnetic disk device 1 and an encoding section 12 of a hard disk controller 4 according to this embodiment and flows of data. An error detector 112 judges whether or not the encoding or decoding of data has succeeded, using the inputted error detecting code. The remaining configuration has been already described in FIG. 5, and therefore the same numbers and symbols are given to common components and overlapping description will be omitted.

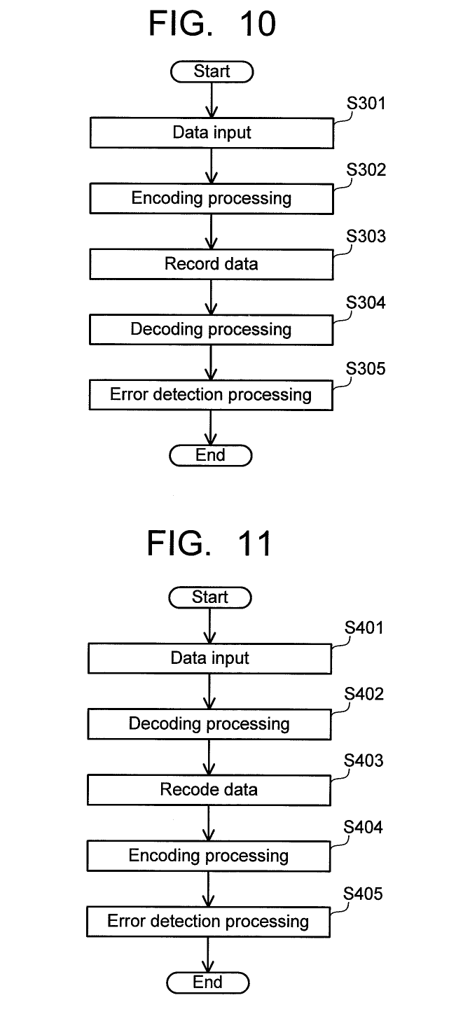

FIG. 10 is a flowchart showing the operation at writing by the encoding section 12 according to this embodiment. FIG. 11 is a flowchart showing the operation at reading by the encoding section 12 according to this embodiment. Hereinafter, the operation of the encoding section 12 according to this embodiment will be described using FIG. 10 and FIG. 11.

### (Operation at Writing of Data)

From the host access control section 11 into the encoding section 12, write data N0 is inputted (Step S301). The multiplexer 102 inputs the write data N0 inputted into the port 0, into the encoder 104. The encoder 104 encodes the inputted write data N0 (Step 5302).

The encoder 104 inputs the encoded write data E(N0) into the port 0 of the multiplexer 106. The multiplexer 106 inputs the inputted write data E(N0) into the register 108. The register 108 records the inputted write data E(N0) thereon (Step 5303). If next write data N1 can be inputted at this moment, the write data N1 is inputted from the host access control section 11 into the encoding section 12.

The register 108 inputs the recorded write data E(N0) into the port 0 of the multiplexer 103. The multiplexer 103 inputs the inputted write data into the decoder 105. The decoder 105 decodes the inputted write data E(N0) (Step S304).

Further, the multiplexer 102 inputs the write data N1 inputted to the port 0, into the encoder 104. The encoder 104 encodes the inputted write data N1. After completion of the decoding of the write data E(N0), the decoder 105 inputs the decoded write data D(E(N0)) into the port 0 of the multiplexer 107. The multiplexer 107 inputs the inputted write data D(E(N0)) into the error detector 112.

The error detector 112 also implements error detection processing of the write data D(E(N0)) inputted from the multiplexer 107 using the error detecting code added to the write data N0 which has been inputted, separately from the write data N0 (Step S305). If the write data before encoding has no error and encoding and decoding of all of the write data have succeeded, the same write data as that before encoding has been obtained, so that the error detector 112 judges that there is no error, that is, the encoding has succeeded. On the other hand, when there is an error in the write data before encoding, or if encoding and decoding of all of the write data have failed even one bit, the error detector 112 judges that there is an error, that is, the encoding has failed.

When any error is not detected, the error detector 112 outputs the judgment result of encoding success. On the other hand, when an error is detected, the error detector 112 outputs the judgment result of encoding failure. The register 108 outputs the recorded write data E(N0), but when the judgment result of encoding failure is outputted, the write data E(N0) is discarded.

Further, if the encoding of the write data N1 has been completed, the encoder 104 inputs the encoded write data E(N1) into the port 0 of the multiplexer 106. The multiplexer 106 inputs the inputted write data E(N1) into the register 108. The register 108 records the inputted write data E(N1). Hereinafter, data processing after the write data N1 is performed in the same manner.

Note that when the error detecting code is added in a data unit different from the data unit of the encoding processing by the encoder 104 and the decoding processing by the decoder 105, the error detecting code is added, for example, in a unit of 256 bits. When the encoder 104 and the decoder 105 can perform processing only in a unit of 128 bits, the error detector 112 performs error detection for every 128 bits that is the unit of encoding or decoding, and implements the error detection processing by the error detecting code after completion of the processing of write data for 256 bits that is the unit by which the error detecting code is added.

In this case, the encoded write data is once recorded in the RAM 2. When the judgment result of encoding success is outputted from the error detector 112, the write data once recorded on the RAM 2 is written into the magnetic recording disk 6, whereas when the judgment result of encoding failure is outputted from the error detector 112, the write data once recorded on the RAM 2 is discarded.

### (Operation at Reading of Data)

The read data N0 is inputted from the disk access control section 14 into the encoding section 12 (Step 5401). The multiplexer 103 inputs the read data N0 inputted to the port 1, into the decoder 105. The decoder 105 decodes the inputted read data N0 (Step S402).

The decoder 105 inputs the decoded read data D(N0) into the port 1 of the multiplexer 106. The multiplexer 106 inputs the inputted read data D(N0) into the register 108. The register 108 records the inputted read data D(N0) thereon (Step S403). If next read data N1 can be inputted at this moment, the read data N1 is inputted from the host access control section 11 into the encoding section 12.

The register 108 inputs the recorded read data D(N0) into the port 1 of the multiplexer 102. The multiplexer 102 inputs the inputted read data D(N0) into the encoder 104. The encoder 104 encodes the inputted read data D(N0) (Step S404).

The multiplexer 103 also inputs the read data N1 inputted to the port 1, into the decoder 105. The decoder 105 decodes the inputted read data N1. After completion of the encoding of the read data D(N0), the encoder 104 inputs the encoded read data E(D(N0)) into the port 1 of the multiplexer 107. The multiplexer 107 inputs the inputted read data E(D(N0)) into the error detector 112.

The error detector 112 implements error detection processing of the read data E(D(N0)) inputted from the multiplexer 107 using the error detecting code added to the read data N0 which has been inputted separately from the read data N0 (Step S405). If the read data before decoding has no error and decoding and encoding of all of the write data have succeeded, the same read data as that before decoding has been obtained, so that the error detector 112 judges that there is no error, that is, the decoding has succeeded. On the other hand, when there is an error in the read data before decoding, or if decoding and encoding of all of the read data have failed even one bit, the error detector 112 judges that there is an error, that is, the decoding has failed.

When any error is not detected, the error detector 112 outputs the judgment result of decoding success. On the other hand, when an error is detected, the error detector 112 outputs the judgment result that the decoding has not been correctly performed. The register 108 outputs the recorded read data D(N0), but when the judgment result of decoding failure is outputted, the read data D(N0) is discarded.

Further, if the decoding of the read data N1 has been completed, the decoder 105 inputs the decoded read data D(N1) into the port 1 of the multiplexer 106. The multiplexer 106 inputs the inputted read data D(N1) into the register 108. The register 108 records the inputted read data D(N1). Hereinafter, data processing after the read data N1 is performed in the same manner. Note that when the error detecting code is added in a data unit different from the encoding data unit, the same processing as that described for the data writing processing is performed.

It can be prevented to output error data and record it onto the magnetic recording disk 6 because whether or not the encoding of data has succeeded is verified when data is written into the magnetic recording disk 6 as described above. It can also be prevented to output and transmit error data because whether or not the decoding of data has succeeded is verified when data is read from the magnetic recording disk 6.

### Third Embodiment

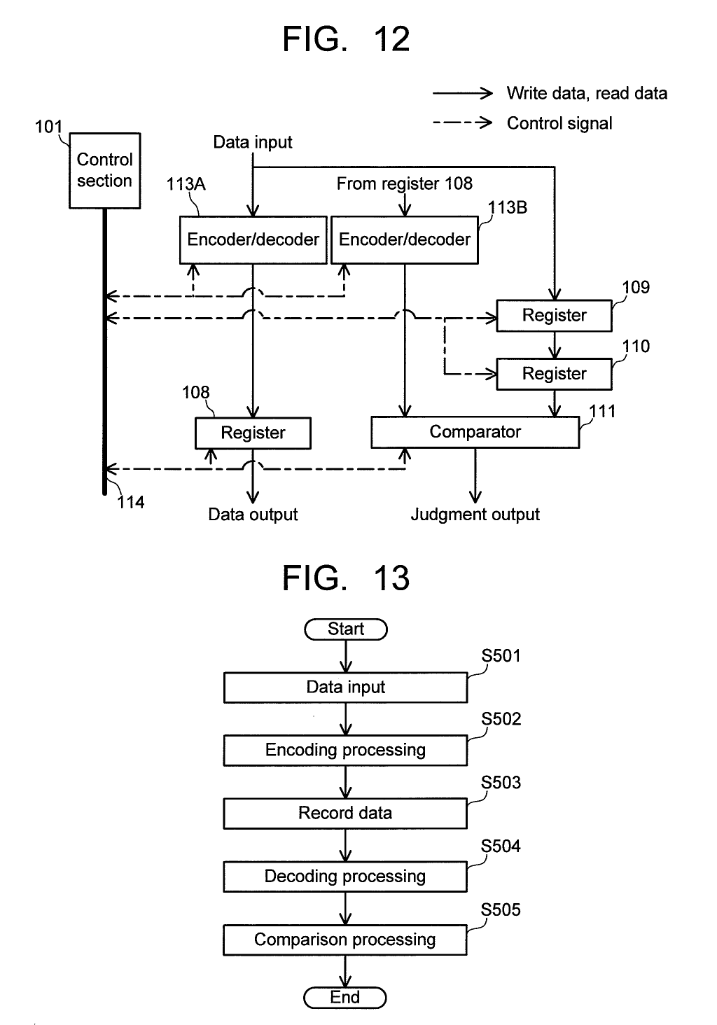

FIG. 12 is an illustration showing a configuration of a magnetic disk device 1 and an encoding section 12 of a hard disk controller 4 according to this embodiment and flows of data. In this embodiment, an encoder/decoder 113 is used which can process encoding and decoding of data by one circuit. Whether the data is encoded or decoded is controlled by a control section 101. The remaining configuration has been already described in FIG. 5, and therefore the same numbers and symbols are given to common components and overlapping description will be omitted. Note that in this embodiment, the flows of write data and read data are the same. Therefore, both flows of the write data and read data are indicated by solid lines.

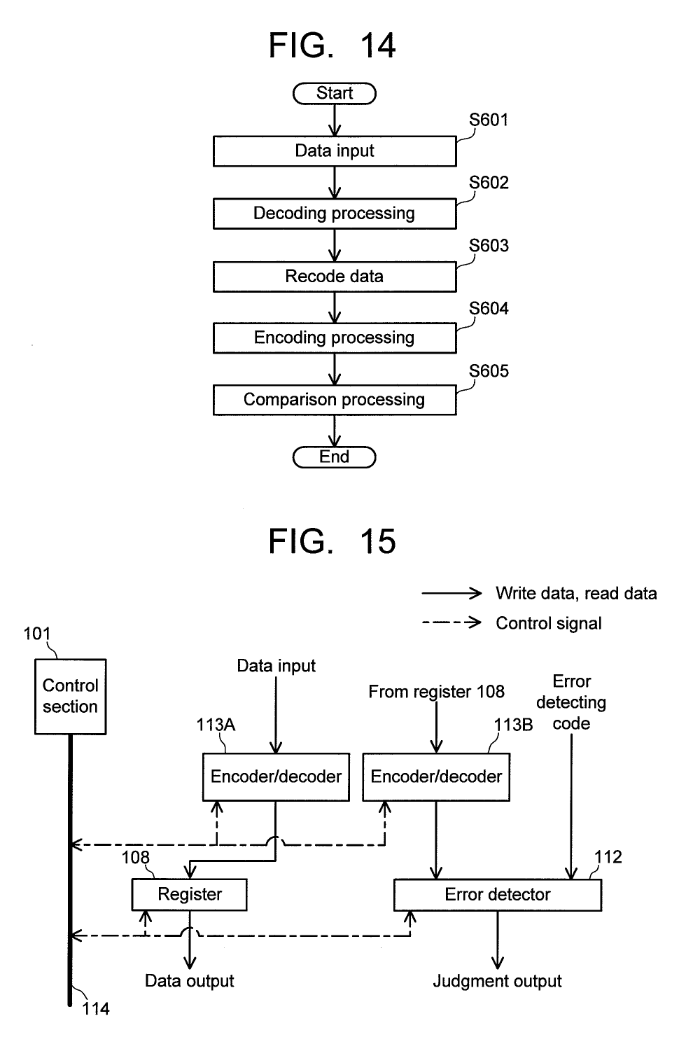

FIG. 13 is a flowchart showing the operation at writing by the encoding section 12 according to this embodiment. FIG. 14 is a flowchart showing the operation at reading by the encoding section 12 according to this embodiment. Hereinafter, the operation of the encoding section 12 of this embodiment will be described using FIG. 13 and FIG. 14.

### (Operation at Writing of Data)

From the host access control section 11 into the encoding section 12, write data N0 is inputted (Step S501). The register 109 records the inputted write data N0 thereon. An encoder/decoder 113A encodes the inputted write data N0 (Step S502).

The encoder/decoder 113A inputs the encoded write data E(N0) into the register 108. The register 108 records the inputted write data E(N0) thereon (Step S503). If next write data N1 can be inputted at this moment, the write data N1 is inputted from the host access control section 11 into the encoding section 12. The register 108 inputs the recorded write data E(N0) into an encoder/decoder 113B.

The encoder/decoder 113B decodes the inputted write data E(N0) (Step S504). The register 109 inputs the recorded write data N0 into the register 110. If next write data N1 has been inputted at this moment, the register 109 records the write data N1 thereon. Further, the encoder/decoder 113A encodes the inputted write data N1. After completion of the decoding of the write data E(N0), an encoder/decoder 113B inputs the decoded write data D(E(N0)) into the comparator 111. The register 110 inputs the recorded write data N0 into the comparator 111.

The comparator 111 compares the inputted two pieces of write data D(E(N0)) and N0 (Step S505). If the two pieces of write data D(E(N0)) and N0 are coincident, the comparator 111 outputs the judgment result of encoding success. On the other hand, when the two pieces of write data D(E(N0)) and N0 are not coincident, the comparator 111 outputs the judgment result of encoding failure. Further, the register 108 outputs the recorded write data E(N0), but when the judgment result of encoding failure is outputted from the comparator 111, the write data E(N0) is discarded.

Further, if the encoding of the write data N1 has been completed, the encoder/decoder 113A inputs the encoded write data E(N1) into the register 108. The register 108 records the inputted write data E(N1). Hereinafter, data processing after the write data N1 is performed in the same manner.

### (Operation at Reading of Data)

From the disk access control section 14 into the encoding section 12, read data N0 is inputted (Step S601). The register 109 records the inputted read data N0 thereon. The encoder/decoder 113A decodes the inputted read data N0 (Step S602).

The encoder/decoder 113A inputs the decoded read data D(N0) into the register 108. The register 108 records the inputted read data D(N0) thereon (Step S603). If next read data N1 can be inputted at this moment, the read data N1 is inputted from the host access control section 11 into the encoding section 12. The register 108 inputs the recorded read data D(N0) into the encoder/decoder 113B.

The encoder/decoder 113B decodes the inputted read data D(N0) (Step S604). The register 109 inputs the recorded read data N0 into the register 110. If the next read data N1 has been inputted at this moment, the register 109 records the read data N1 thereon. Further, the encoder/decoder 113A decodes the inputted write data N1. After completion of the encoding of the read data D(N0), the encoder/decoder 113B inputs the encoded write data E(D(N0)) into the comparator 111. The register 110 inputs the recorded read data N0 into the comparator 111.

The comparator 111 compares the inputted two pieces of read data E(D(N0)) and N0 (Step 5605). If the two pieces of read data E(D(N0)) and N0 are coincident, the comparator 111 outputs the judgment result of decoding success. On the other hand, when the two pieces of read data E(D(N0)) and N0 are not coincident, the comparator 111 outputs the judgment result of decoding failure. Further, the register 108 outputs the recorded read data D(N0), but when the judgment result of decoding failure is outputted from the comparator 111, the read data D(N0) is discarded.

Further, if the decoding of the read data N1 has been completed, the encoder/decoder 113A inputs the decoded read data D(N1) into the register 108. The register 108 records the inputted read data D(N1). Hereinafter, data processing after the read data N1 is performed in the same manner.

### Fourth Embodiment

FIG. 15 is an illustration showing a configuration of a magnetic disk device 1 and an encoding section 12 of a hard disk controller 4 according to this embodiment and flows of data. In this embodiment, an encoder/decoder 113 is used. Whether the data is encoded or decoded is controlled by a control section 101. The configuration of the encoding section 12 according to this embodiment has been already described in FIG. 5, FIG. 9 and FIG. 12. Therefore the same numbers and symbols are given to common components and overlapping description will be omitted. Further, both flows of the write data and read data are indicated by solid lines.

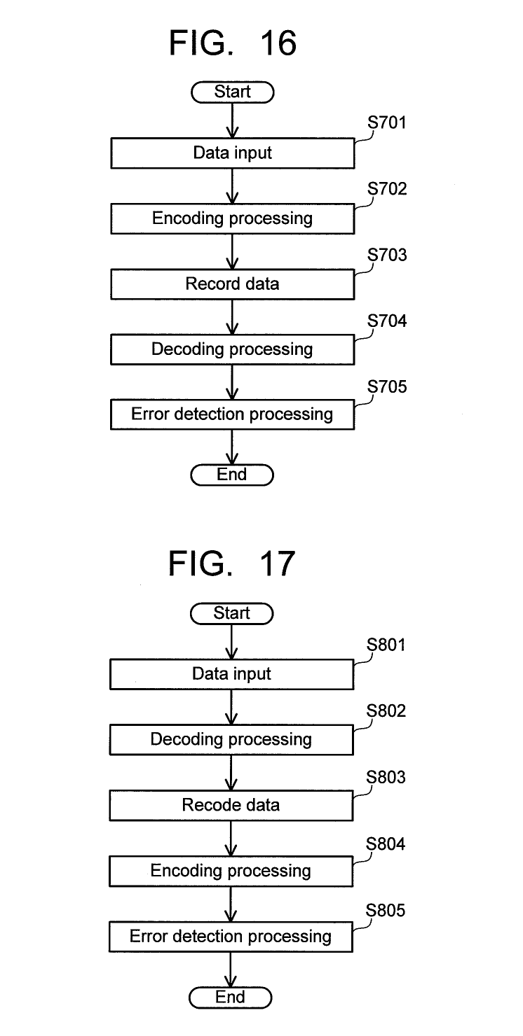

FIG. 16 is a flowchart showing the operation at writing by the encoding section 12 of this embodiment. FIG. 17 is a flowchart showing the operation at reading by the encoding section 12 of this embodiment. Hereinafter, the operation of the encoding section 12 of this embodiment will be described using FIG. 16 and FIG. 17.

### (Operation at Writing of Data)

From the host access control section 11 into the encoding section 12, write data N0 is inputted (Step S701). An encoder/decoder 113A encodes the inputted write data N0 (Step S702).

The encoder/decoder 113A inputs the encoded write data E(N0) into the register 108. The register 108 records the inputted write data E(N0) thereon (Step S703). If next write data N1 can be inputted at this moment, the write data N1 is inputted from the host access control section 11 into the encoding section 12. The register 108 inputs the recorded write data E(N0) into an encoder/decoder 113B.

The encoder/decoder 113B decodes the inputted write data E(N0) (Step S704). The encoder/decoder 113A encodes the inputted write data N1. After completion of the decoding of the write data E(N0), the encoder/decoder 113B inputs the decoded write data D(E(N0)) into an error detector 112.

The error detector 112 also implements error detection processing of the write data D(E(N0)) inputted from the encoder/decoder 113B using the error detecting code which has been inputted, separately from the write data N0 (Step S705). When any error is not detected, the error detector 112 outputs the judgment result of encoding success. On the other hand, when an error is detected, the error detector 112 outputs the judgment result of encoding failure. The register 108 outputs the recorded write data E(N0), but when the judgment result of encoding failure is outputted from the error detector 112, the write data E(N0) is discarded.

Further, if the encoding of the write data N1 has been completed, the encoder/decoder 113A inputs the encoded write data E(N1) into the register 108. The register 108 records the inputted write data E(N1). Hereinafter, data processing after the write data N1 is performed in the same manner.

### (Operation at Reading of Data)

From the disk access control section 14 into the encoding section 12, read data N0 is inputted (Step S801). The encoder/decoder 113A decodes the inputted read data N0 (Step S802).

The encoder/decoder 113A inputs the decoded read data D(N0) into the register 108. The register 108 records the inputted read data D(N0) thereon (Step S803). If next read data N1 can be inputted at this moment, the read data N1 is inputted from the host access control section 11 into the encoding section 12. The register 108 inputs the recorded read data D(N0) into the encoder/decoder 113B.

The encoder/decoder 113B encodes the inputted read data D(N0) (Step S804). The encoder/decoder 113A decodes the inputted read data N1. After completion of the encoding of the read data D(N0), the encoder/decoder 113B inputs the encoded read data E(D(N0)) into the error detector 112.

The error detector 112 implements error detection processing of the read data E(D(N0)) inputted from the encoder/decoder 113B using the error detecting code (Step S805). When any error is not detected, the error detector 112 outputs a judgment result that the decoding has succeeded. On the other hand, when an error is detected, the error detector 112 outputs a judgment result that the decoding has not been correctly performed. The register 108 also outputs the recorded read data D(N0), but when the judgment result of decoding failure is outputted from the error detector 112, the read data D(N0) is discarded.

Further, if the decoding of the read data N1 has been completed, the encoder/decoder 113A inputs the decoded read data D(N1) into the register 108. The register 108 records the inputted read data D(N1). Hereinafter, data processing is performed in the same manner.

### Fifth Embodiment

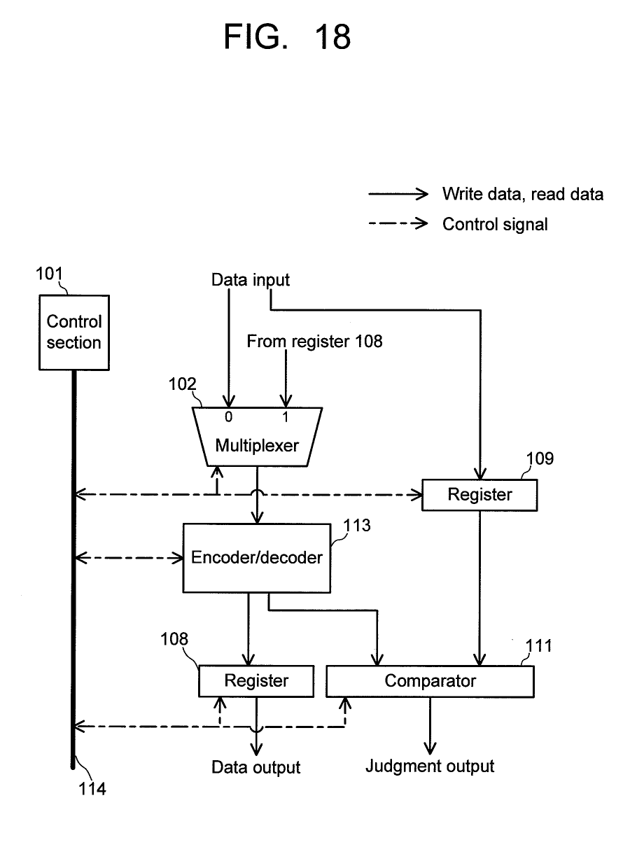

FIG. 18 is an illustration showing a configuration of a magnetic disk device 1 and an encoding section 12 of a hard disk controller 4 according to this embodiment and flows of data. In this embodiment, an encoder/decoder 113 is used so that the configuration can be simplified. The encoder/decoder 113 is used. Whether the data is encoded or decoded is controlled by a control section 101. The components of the encoding section 12 according to this embodiment have been already described in FIG. 5 and FIG. 12. Therefore, the same numbers and symbols are given to common components and overlapping description will be omitted. Further, both flows of the write data and read data are indicated by solid lines.

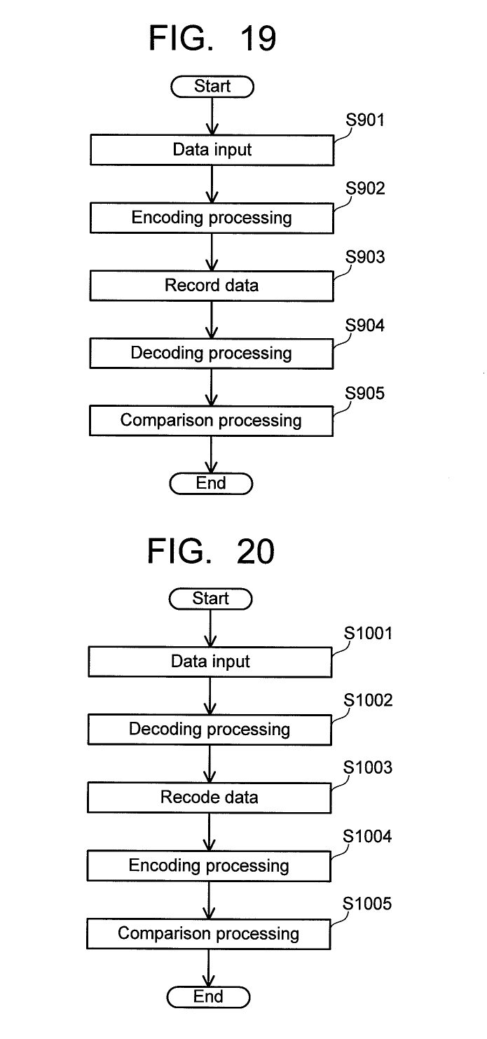

FIG. 19 is a flowchart showing the operation at writing by the encoding section 12 of this embodiment. FIG. 20 is a flowchart showing the operation at reading by the encoding section 12 of this embodiment. Hereinafter, the operation of the encoding section 12 of this embodiment will be described using FIG. 19 and FIG. 20.

### (Operation at Writing of Data)

From the host access control section 11 into the encoding section 12, write data N0 is inputted (Step S901). The register 109 records the inputted write data N0 thereon. The multiplexer 102 inputs the write data N0 inputted into the port 0, into an encoder/decoder 113. The encoder/decoder 113 encodes the inputted write data N0 (Step S902).

The encoder/decoder 113 inputs the encoded write data E(N0) into the register 108. The register 108 records the inputted write data E(N0) thereon (Step S903). The register 108 inputs the recorded write data E(N0) into the port 1 of the multiplexer 102. The multiplexer 102 inputs the write data E(N0) inputted into the port 1, into the encoder/decoder 113.

The encoder/decoder 113 decodes the inputted write data E(N0) (Step S904). After completion of the decoding of the write data E(N0), the encoder/decoder 113 inputs the decoded write data D(E(N0)) into the comparator 111. The register 109 inputs the recorded write data N0 into the comparator 111.

The comparator 111 compares the inputted two pieces of write data D(E(N0)) and N0 (Step S905). If the two pieces of write data D(E(N0)) and N0 are coincident, the comparator 111 outputs the judgment result of encoding success. On the other hand, when the two pieces of write data D(E(N0)) and N0 are not coincident, the comparator 111 outputs the judgment result of encoding failure. Further, the register 108 outputs the recorded write data E(N0), but when the judgment result of encoding failure is outputted from the comparator 111, the write data E(N0) is discarded. Hereinafter, data processing after the write data N0 is performed in the same manner.

### (Operation at Reading of Data)

From the disk access control section 14 into the encoding section 12, read data N0 is inputted (Step S1001). The register 109 records the inputted read data N0 thereon. The multiplexer 102 inputs the read data N0 inputted into the port 0, into the encoder/decoder 113. The encoder/decoder 113 decodes the inputted read data N0 (Step S1002).

The encoder/decoder 113 inputs the decoded read data D(N0) into the register 108. The register 108 records the inputted read data D(N0) thereon (Step S1003). The register 108 inputs the recorded read data D(N0) into the port 1 of the multiplexer 102. The multiplexer 102 inputs the read data D(N0) inputted into the port 1, into the encoder/decoder 113.

The encoder/decoder 113 encodes the inputted read data D(N0) (Step S1004). After completion of the encoding of the read data D(N0), the encoder/decoder 113 inputs the encoded read data E(D(N0)) into the comparator 111. The register 109 inputs the recorded read data N0 into the comparator 111.

The comparator 111 compares the inputted two pieces of read data E(D(N0)) and N0 (Step S1005). When the two pieces of read data E(D(N0)) and N0 are coincident, the comparator 111 outputs the judgment result of decoding success. On the other hand, when the two pieces of read data E(D(N0)) and N0 are not coincident, the comparator 111 outputs the judgment result of decoding failure. Further, the register 108 outputs the recorded read data D(N0), but when the judgment result of decoding failure is outputted from the comparator 111, the read data D(N0) is discarded. Hereinafter, data processing after the read data N0 is performed in the same manner.

### Sixth Embodiment

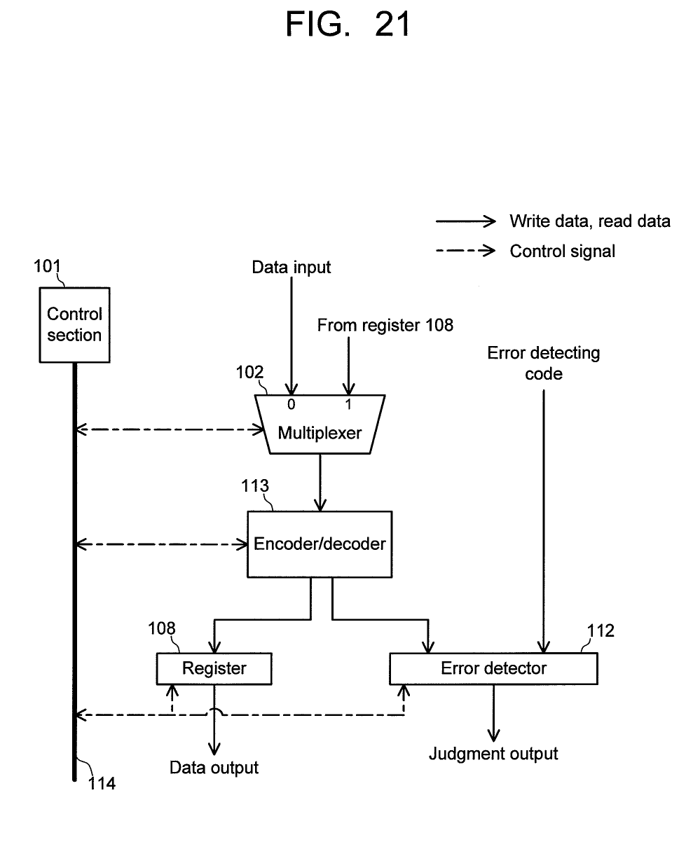

FIG. 21 is an illustration showing a configuration of a magnetic disk device 1 and an encoding section 12 of a hard disk controller 4 according to this embodiment and flows of data. In this embodiment, an encoder/decoder 113 is used so that the configuration can be simplified. The encoder/decoder 113 is used. Whether the data is encoded or decoded is controlled by a control section 101. The components of the encoding section 12 according to this embodiment have been already described in FIG. 5, FIG. 9 and FIG. 12. Therefore, the same numbers and symbols are given to common components and overlapping description will be omitted. Further, both flows of the write data and read data are indicated by solid lines.

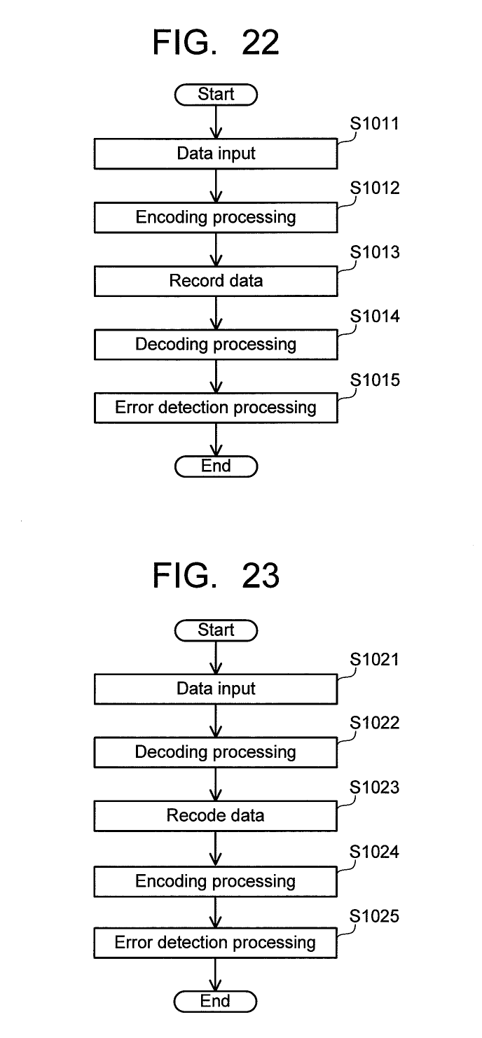

FIG. 22 is a flowchart showing the operation at writing by the encoding section 12 of this embodiment. FIG. 23 is a flowchart showing the operation at reading by the encoding section 12 of this embodiment. Hereinafter, the operation of the encoding section 12 of this embodiment will be described using FIG. 22 and FIG. 23.

### (Operation at Writing of Data)

From the host access control section 11 into the encoding section 12, write data N0 is inputted (Step S1011). The multiplexer 102 inputs the write data N0 inputted into the port 0, into the encoder/decoder 113. The encoder/decoder 113 encodes the inputted write data N0 (Step S1012).

The encoder/decoder 113 inputs the encoded write data E(N0) into the register 108. The register 108 records the inputted write data E(N0) thereon (Step S1013). The register 108 inputs the recorded write data E(N0) into the port 1 of the multiplexer 102. The multiplexer 102 inputs the write data E(N0) inputted into the port 1, into the encoder/decoder 113.

The encoder/decoder 113 decodes the inputted write data E(N0) (Step S1014). After completion of the decoding of the write data E(N0), the encoder/decoder 113 inputs the decoded write data D(E(N0)) into the error detector 112.

The error detector 112 also implements error detection processing of the write data D(E(N0)) inputted from the encoder/decoder 113 using the error detecting code which has been inputted, separately from the write data N0 (Step S1015). When any error is not detected, the error detector 112 outputs the judgment result of encoding success. On the other hand, when an error is detected, the error detector 112 outputs the judgment result of encoding failure. The register 108 outputs the recorded write data E(N0), but when the judgment result of encoding failure is outputted from the error detector 112, the write data E(N0) is discarded. Hereinafter, data processing after the write data N0 is performed in the same manner.

### (Operation at Reading of Data)

From the disk access control section 14 into the encoding section 12, read data N0 is inputted (Step S1021). The multiplexer 102 inputs the read data N0 inputted into the port 0, into the encoder/decoder 113. The encoder/decoder 113 decodes the inputted read data N0 (Step S1022).

The encoder/decoder 113 inputs the decoded read data D(N0) into the register 108. The register 108 records the inputted read data D(N0) thereon (Step S1023). The register 108 inputs the recorded read data D(N0) into the port 1 of the multiplexer 102. The multiplexer 102 inputs the read data D(N0) inputted into the port 1, into the encoder/decoder 113.

The encoder/decoder 113 encodes the inputted read data D(N0) (Step S1024). After completion of the encoding of the read data D(N0), the encoder/decoder 113 inputs the encoded read data E(D(N0)) into the error detector 112.

The error detector 112 also implements error detection processing of the read data E(D(N0)) inputted from the encoder/decoder 113 using the error detecting code which has been inputted, separately from the read data N0 (Step S1025). When any error is not detected, the error detector 112 outputs the judgment result of decoding success. On the other hand, when an error is detected, the error detector 112 outputs the judgment result of decoding failure. The register 108 outputs the recorded read data D(N0), but when the judgment result of decoding failure is outputted from the error detector 112, the read data D(N0) is discarded. Hereinafter, data processing after the read data N0 is performed in the same manner.

### Seventh Embodiment

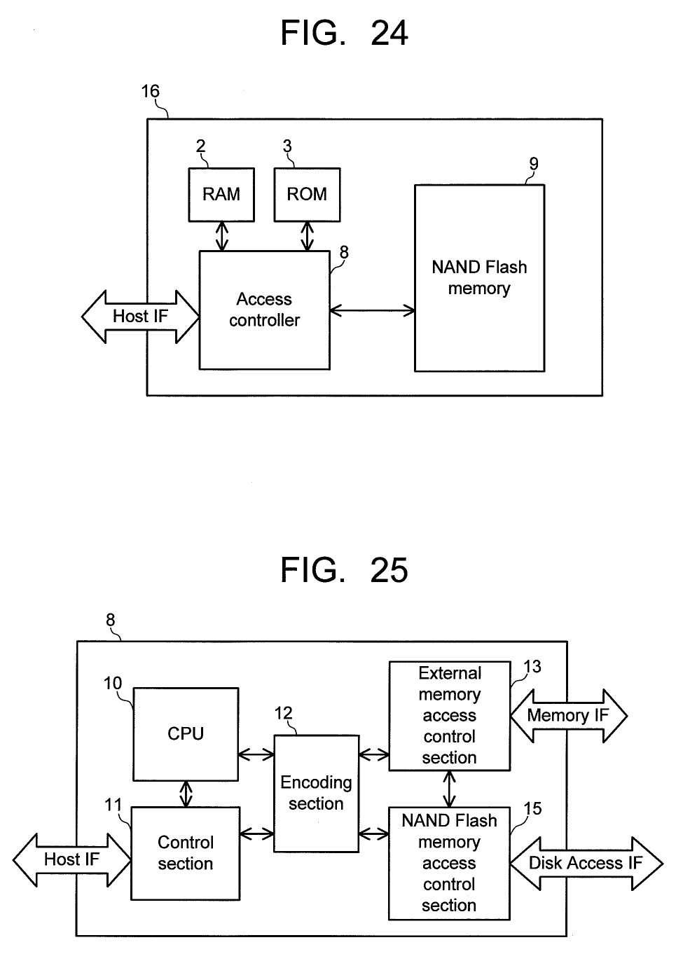

FIG. 24 is a diagram showing a configuration of a memory device 16 according to this embodiment. FIG. 25 is a diagram showing a configuration of a NAND flash memory access controller 8 according to an application example 1. The memory device 16 and the NAND flash memory access controller 8 constitute information processing devices, respectively. Though a memory device using the NAND flash memory as a memory will be described as a memory in this embodiment, another rewritable memory can also be used.

A NAND flash memory (storage medium) 9 records data thereon. The NAND flash memory access controller 8 controls the operation of the entire NAND flash memory. A NAND flash memory access control section 15 comprises a NAND flash memory access interface and writes/read data to/from the NAND flash memory 9. An encoding section 12 is the encoding section 12 which has been described in the first to sixth embodiments. The remaining configuration has already been described in FIG. 1 and FIG. 2. Therefore, the same numbers and symbols are given to common components and overlapping description will be omitted.

### Eighth Embodiment

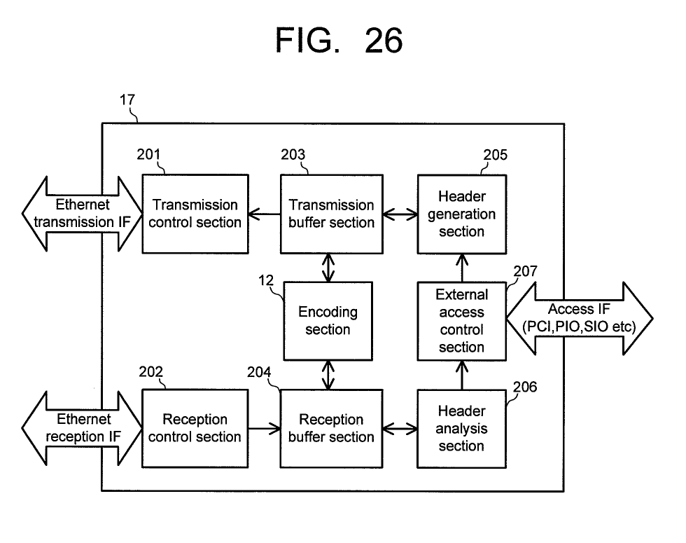

FIG. 26 is a diagram showing a configuration of an Ethernet controller 17 according to this embodiment. This Ethernet controller 17 constitutes an information processing device. A reception control section 202 receives a frame from an Ethernet reception interface and inputs it into a reception buffer 204 according to an Ethernet communication protocol. The reception buffer 204 buffers the frame received by the reception control section 202. A header analysis section 206 analyses a header of the frame inputted into the reception buffer 204. An encoding section 12 is the encoding section 12 which has been described in the first to sixth embodiments, and decodes a portion which has been encoded in the frame in the reception buffer 204.

An external access control section 207 transmits the decoded data to an external device via an external access interface such as PCI (Peripheral Component Interconnect), PIO (Parallel Input/Output), SIO (Serial Input/Output) or the like. The external access control section 207 further receives transmission destination information and transmission data from the external device via the external access interface. The transmission buffer 203 buffers the transmission destination information and transmission data received by the external access control section 207.

A header generation section 205 generates a header of the data from the transmission destination information of the transmission buffer 203 and applies it to the data. The encoding section 12 encodes a necessary portion of the data inputted into the transmission buffer 203. The transmission control section 201 transmits an Ethernet frame created from the generated header and transmission data, from an Ethernet transmission interface according to the Ethernet communication protocol.

Note that devices employing the Ethernet controller 17 include network router, network hub, PC (Personal Computer), digital appliance and so on. The communication standard is not limited to Ethernet but may be USB (Universal Serial Bus) or the like.

As described above, it can be prevented to transmit error data because whether or not encoding or decoding of data has succeeded is verified.

Note that the encoder 104, the decoder 105, the encoder/decoder 113 and the error detector 112 of the encoding section 12 according to the first to eighth embodiments are provided with circuits for buffering as necessary. Buffering may be performed for the purpose of adjustment when the data unit of the encoder 104, the decoder 105, or the encoder/decoder 113 does not match the data unit of the error detecting code and for the purpose of control in previous or subsequent circuit. The buffering circuits are used also when encoding and decoding of data is performed using the encoder 104, the decoder 105 or the encoder/decoder 113, independent of writing or reading of data to/from the magnetic recording disk 6.

Further, the unit of data input into the encoding section 12 may or may not be based on every encoding or decoding data unit. When it is not based on every encoding or decoding data unit, the inputted data is processed for every encoding or decoding data unit after buffering. The data output unit from the encoding section 12 may or may not be based on every encoding or decoding data unit. When it is not based on every encoding data unit, the encoded or decoded information is buffered and the data is outputted based on every output unit.

### Other Embodiments

The embodiments of the present invention are not limited to the above-describe embodiments, but can be extended or changed, and the extended and changed embodiments are also included in the technical scope of the present invention.

What is claimed is:

1. An information processing device, comprising:
a first encoder configured to encode data having an error detecting code in a first encoding format to generate first data;
a register configured to record the first data generated by the first encoder;
a second encoder configured to encode the first data recorded on the register in a second encoding format corresponding to decoding of the first encoding format to generate second data; and
an error detector configured to perform error detection on the second data based on the error detecting code added to the data;
wherein
the register configured to output the first data recorded thereon when the result of the error detection shows no error.

2. The information processing device of claim 1, further comprising a recording section configured to record the first data outputted from the register on a recording medium.

3. The information processing device of claim 1, wherein
the first encoder configured to encode a third data next to the first data in a first encoding format to generate forth data;
the register configured to record the forth data after output the first data recorded thereon.

4. An information processing device, comprising:
a decoder configured to decode data having an error detecting code in a predetermined decoding format to generate first data;
a register configured to record the first data generated by the decoder;
an encoder configured to encode the first data recorded on the register in a predetermined encoding format corresponding to the predetermined decoding format to generate second data; and
an error detector configured to perform error detection on the second data based on the error detecting code added to the data;
wherein
the register configured to output the first data recorded thereon when the result of the error detection shows no error

5. An information processing method, comprising:
encoding data having an error detecting code in a first encoding format to generate first data;
recording the first data on a register;
encoding the first data recorded on the register in a second encoding format corresponding to decoding of the first encoding format to generate second data;
performing error detection on the second data based on the error detecting code added to the data; and
outputting the first data recorded on the register when the result of the error detection shows no error.
